(19) United States
(12) Patent Application Publication
(10) Pub. No.: US 2021/0116490 A1
(43) Pub. Date: Apr. 22, 2021

(54) ANTENNA DIRECTION ADJUSTMENT APPARATUS, ANTENNA DIRECTION ADJUSTMENT SYSTEM, AND METHOD THEREFOR

(71) Applicant: NEC Corporation, Tokyo (JP)

(72) Inventor: Nobuyuki TANAKA, Tokyo (JP)

(73) Assignee: NEC Corporation, Tokyo (JP)

(21) Appl. No.: 16/494,583

(22) PCT Filed: Feb. 8, 2018
(86) PCT No.: PCT/JP2018/004389

§ 371 Date: Sep. 16, 2019

(30) Foreign Application Priority Data
Mar. 17, 2017 (JP) 2017-052922

(51) Int. Cl. G01R 29/10; H04B 1/16; H04B 1/18; H04B 17/318

(52) U.S. Cl. CPC G01R 29/10; H04B 17/318; H04B 1/18; H04B 1/1607

(57) ABSTRACT

An antenna direction adjustment apparatus according to the present disclosure includes an acquisition unit configured to acquire at least one of an elevation angle and an azimuth angle of an antenna, and a reception level of the antenna at the angle of the antenna, a generation unit configured to generate first information based on the reception level of the antenna and generate second information based on the reception level of the antenna and the first information, and a transmission unit configured to transmit the angle of the antenna and the second information to a display device. The first information is a coefficient that becomes larger as the reception level of the antenna becomes higher. In this way, it is possible to provide an antenna direction adjustment apparatus capable of alleviating the difficulty of the operation for adjusting the direction of an antenna.

### TECHNICAL FIELD

The present invention relates to an antenna direction adjustment apparatus, a display device, an antenna direction adjustment system, and a method therefor. In particular, the present disclosure relates to an antenna direction adjustment apparatus, a display device, an antenna direction adjustment system, and a method therefor that are used when a direction of an antenna is adjusted between opposed radio communication apparatuses.

### BACKGROUND ART

In order to perform radio communication between opposed radio communication apparatuses such as P2P (Point to Point), it is important to adjust the direction of an antenna to an appropriate direction so that a reception level between the opposed radio communication apparatuses is maximized.

An antenna adjustment between opposed radio communication apparatuses requires very accurate precision. In particular, as the frequency of an emitted beam increases, its width decreases, thus making the operation for adjusting the direction of the antenna very difficult.

Patent Literature 1 discloses a technique in which changes in the reception level of an antenna is monitored while changing the direction of the antenna and the direction of the antenna is adjusted to a direction in which the reception level has a peak value.

### CITATION LIST

### Patent Literature

### Patent Literature 1: Japanese Unexamined Patent Application Publication No. 2004-253921

### SUMMARY OF INVENTION

### Technical Problem

However, because of the characteristic of the shape of the reception-level pattern of the antenna, changes in the reception level that occur according to changes in the angle of the antenna become smaller as the antenna is directed toward the opposed antenna. Therefore, in the technique disclosed in Patent Literature 1, it is difficult to determine whether the adjusted direction and the degree of the adjustment are appropriate or not in the region where the changes in the reception level that occur according to the changes in the angle of the antenna is small. As a result, there is a problem that it takes time to find the peak value of the reception level. Further, in the technique disclosed in Patent Literature 1, there is a problem that an error is likely to occur in the adjustment of the direction of an antenna.

Further, there is a problem that when the antenna is operated in a state where there is an error in the adjusted direction of the antenna, its gain further deteriorates when, for example, the antenna is shaken due to a wind.

The present invention has been made to solve the above-described problems and an object thereof is to provide an antenna direction adjustment apparatus, a display device, an antenna direction adjustment system, and a method therefor capable of alleviating the difficulty of the operation for adjusting the direction of an antenna.

### Solution to Problem

An antenna direction adjustment apparatus according to a first aspect of the present invention includes: acquisition means for acquiring at least one of an elevation angle and an azimuth angle of an antenna, and a reception level of the antenna at the angle; generation means for generating first information based on the reception level, and generating second information based on the reception level and the first information; and transmission means for transmitting the angle and the second information to a display device, in which the first information is a coefficient that becomes larger as the reception level becomes higher.

A display device according to a second aspect of the present invention includes: receiving means for receiving at least one of an elevation angle and an azimuth angle of an antenna, and second information from an antenna direction adjustment apparatus; and display means for displaying the angle and the second information while associating them with each other, in which the second information is information based on the reception level of the antenna and first information, and the first information is a coefficient that becomes larger as the reception level of the antenna becomes higher.

An antenna direction adjustment system according to a third aspect of the present invention includes an antenna direction adjustment apparatus and a display device, in which the antenna direction adjustment apparatus includes acquisition means for acquiring at least one of an elevation angle and an azimuth angle of an antenna, and a reception level of the antenna at the angle, the antenna direction adjustment apparatus or the display device includes generation means for generating first information based on the reception level, and generating second information based on the reception level and the first information, the display device includes display means for displaying the angle and the second information while associating them with each other, and the first information is a coefficient that becomes larger as the reception level of the antenna becomes higher.

A method performed in an antenna direction adjustment apparatus according to a fourth aspect of the present invention includes: acquiring at least one of an elevation angle and an azimuth angle of an antenna, and a reception level of the antenna at the angle; generating first information based on the reception level, the first information being a coefficient that becomes larger as the reception level becomes higher; generating second information based on the reception level and the first information; and transmitting the angle and the second information to a display device.

A method performed in a display device according to a fifth aspect of the present invention includes: receiving at least one of an elevation angle and an azimuth angle of an antenna, and second information from an antenna direction adjustment apparatus; and displaying the angle and the second information while associating them with each other, in which the second information is information based on the reception level of the antenna and first information, and the first information is a coefficient that becomes larger as the reception level of the antenna becomes higher.

A method performed in an antenna direction adjustment system according to a sixth aspect of the present invention includes: acquiring at least one of an elevation angle and an azimuth angle of an antenna, and a reception level of the antenna at the angle; generating first information based on the reception level, the first information being a coefficient that becomes larger as the reception level becomes higher; generating second information based on the reception level and the first information; and displaying the angle and the second information while associating them with each other.

### Advantageous Effects of Invention

According to the present invention, it is possible to provide an antenna direction adjustment apparatus, a display device, an antenna direction adjustment system, and a method therefor capable of alleviating the difficulty of the operation for adjusting the direction of an antenna.

### BRIEF DESCRIPTION OF DRAWINGS

FIG. 1 is a block diagram showing a configuration example of an antenna direction adjustment system according to a first example embodiment of the present invention;

FIG. 2 is a block diagram showing a configuration example of an antenna direction adjustment apparatus according to the first example embodiment of the present invention;

FIG. 3 is a graph for explaining first information according to the first example embodiment of the present invention;

FIG. 4 is a block diagram showing a configuration example of a display device according to a first example embodiment of the present invention;

FIG. 5 is a graph for explaining a comparison between an image displayed in a display device according to the first example embodiment of the present invention and that according to a comparative example;

FIG. 6 is a graph for explaining a comparison between an image displayed in a display device according to the first example embodiment of the present invention and that according to a comparative example;

FIG. 7 is a graph for explaining a comparison between an image displayed in a display device according to the first example embodiment of the present invention and that according to a comparative example;

FIG. 8 is a graph for explaining a comparison between an image displayed in a display device according to the first example embodiment of the present invention and that according to a comparative example;

FIG. 9 is a flowchart showing an example of processes performed by an antenna direction adjustment apparatus according to the first example embodiment of the present invention;

FIG. 10 is a flowchart showing an example of processes performed by a display device according to the first example embodiment of the present invention;

FIG. 11 is a block diagram showing a configuration example of an antenna direction adjustment apparatus according to a modified example of the first example embodiment of the present invention;

FIG. 12 is a block diagram showing a configuration example of a display device according to a modified example of the first example embodiment of the present invention;

FIG. 13 is a block diagram showing a configuration example of an antenna direction adjustment apparatus according to a second example embodiment of the present invention;

FIG. 14 is a graph showing an example of first information according to the second example embodiment of the present invention;

FIG. 15 is a graph showing another example of the first information according to the second example embodiment of the present invention;

FIG. 16 is a graph for explaining a specific example of a method for generating first information according to the second example embodiment of the present invention when a reception level is larger than a predetermined threshold;

FIG. 17 is a graph for explaining a specific example of a method for generating first information according to the second example embodiment of the present invention when a reception level is larger than a predetermined threshold;

FIG. 18 is a block diagram showing a configuration example of an antenna direction adjustment apparatus according to a third example embodiment of the present invention;

FIG. 19 is a block diagram showing a configuration example of a display device according to the third example embodiment of the present invention;

FIG. 20 is a graph for explaining a comparison between an image displayed in a display device according to the third example embodiment of the present invention and that according to a comparative example;

FIG. 21 is a graph for explaining a comparison between an image displayed in a display device according to the third example embodiment of the present invention and that according to a comparative example; and

FIG. 22 shows another example of an image displayed in a display device according to the third example embodiment of the present invention.

### DESCRIPTION OF EMBODIMENTS

Example embodiments according to the present invention will be described hereinafter in detail with reference to the drawings. The same or corresponding elements are denoted by the same symbols throughout the drawings, and duplicated explanations are omitted as necessary for the sake of clarity of the explanations.

### First Example Embodiment

Firstly, an antenna direction adjustment system 100 according to a first example embodiment of the present invention is described with reference to a block diagram shown in FIG. 1. The antenna direction adjustment system 100 includes an antenna direction adjustment apparatus 10 and a display device 20.

For example, the antenna direction adjustment apparatus 10 is used by attaching it to an antenna 1 of a radio communication apparatus that performs radio communication according to the P2P or to a radio device 2 connected to the antenna 1. Note that the antenna direction adjustment apparatus 10 may be disposed inside the radio device 2. Note that the antenna 1 is, for example, a parabolic antenna.

The display device 20 is, for example, a portable information terminal such as a tablet-type terminal. Note that the antenna direction adjustment apparatus 10 and the display device 20 may be connected to each other through a cable or may be wirelessly connected.

The antenna direction adjustment apparatus 10 and the display device 20 are used for adjusting the direction of the antenna 1 when, for example, the antenna 1 is installed. Note that the adjustment of the direction of the antenna 1 means adjusting the direction of the antenna 1 so that the reception level of a signal transmitted from an antenna of an opposed radio communication apparatus in the antenna 1 is maximized.

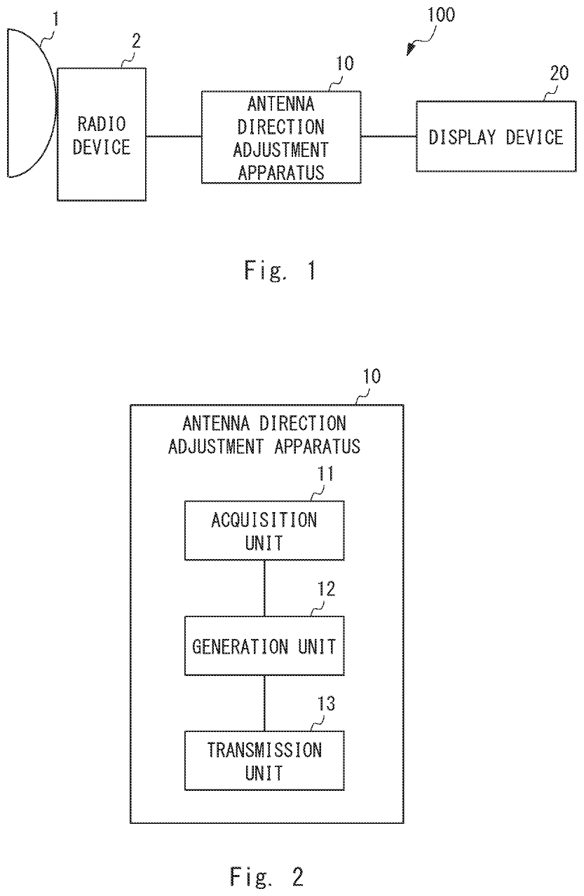

Next, a configuration example of the antenna direction adjustment apparatus 10 according to the first example embodiment is described with reference to a block diagram shown in FIG. 2. The antenna direction adjustment apparatus 10 includes an acquisition unit 11, a generation unit 12, and a transmission unit 13.

The acquisition unit 11 acquires at least one of an elevation angle and an azimuth angle of the antenna 1. In the following description, at least one of the elevation angle and the azimuth angle of the antenna 1 is also referred to as the angle of the antenna 1. Note that the acquisition unit 11 acquires the angle of the antenna 1 by using, for example, an angle sensor such as a gyroscopic sensor.

Further, the acquisition unit 11 acquires a reception level of the antenna 1 at the acquired angle of the antenna 1. The acquisition unit 11 acquires the reception level of the antenna 1 from, for example, the radio device 2. Then, the acquisition unit 11 outputs the acquired angle of the antenna 1 and the reception level of the antenna 1 to the generation unit 12.

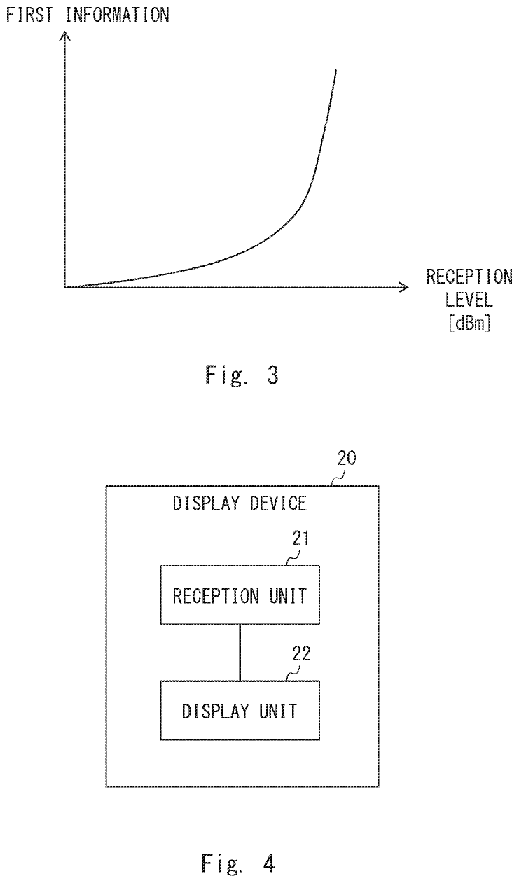

The generation unit 12 receives the angle of and the reception level of the antenna 1 from the acquisition unit 11. Further, the generation unit 12 generates first information based on the received reception level. Note that the first information is a coefficient that becomes larger as the reception level becomes higher as shown in FIG. 3. Note that the coefficient shown in FIG. 3 is merely an example and the first information may be any kind of coefficient as long as it becomes larger as the reception level becomes higher.

Further, the generation unit 12 generates second information based on the reception level of the antenna 1 and the first information. For example, the generation unit 12 generates the second information by multiplying the reception level of the antenna 1 by the first information. For example, when the unit of the reception level is dBm and the unit of the first information is V/dBm, a reception-level voltage [V] is generated as the second information.

The generation unit 12 outputs the angle of the antenna 1 and the second information to the transmission unit 13.

The transmission unit 13 receives the angle of the antenna 1 and the second information from the generation unit 12. Further, the transmission unit 13 transmits the received angle of the antenna 1 and the second information to the display device 20.

Next, the display device 20 according to the first example embodiment of the present invention is described with reference to a block diagram shown in FIG. 4. The display device 20 includes a reception unit 21 and a display unit 22.

The reception unit 21 receives the angle of the antenna 1 and the second information from the antenna direction adjustment apparatus 10. Further, the reception unit 21 outputs the received angle of the antenna 1 and the second information to the display unit 22.

The display unit 22 receives the angle of the antenna 1 and the second information from the reception unit 21. Further, the display unit 22 displays the angle of the antenna 1 and the second information while associating them with each other. In this way, an operator can adjust the direction of the antenna 1 while viewing the display in which the angle of the antenna 1 is associated with the second information.

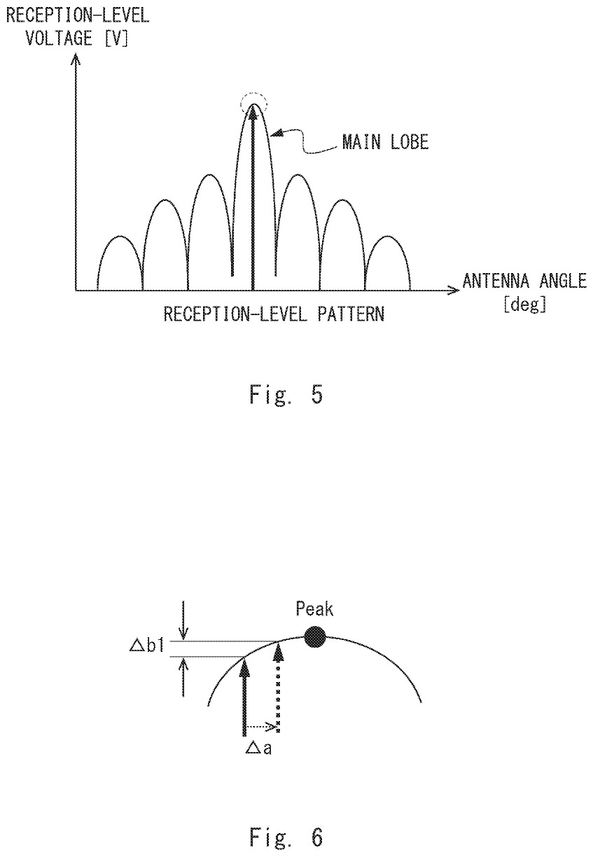

Next, a comparison between an image displayed in the display device according to the first example embodiment and an image according to a comparative example is described with reference to FIGS. 5 to 8. Note that FIGS. 5 to 8 show example cases where the angle of an antenna and its reception-level voltage [V] are displayed while they are associated with each other.

FIGS. 5 and 6 show an example of images in a case where a reception-level voltage [V] is generated by multiplying a reception level [dBm] by a fixed coefficient [V/dBm] without using the first information.

FIG. 5 shows a main lobe located at the center and a plurality of side lobes in both sides thereof. In the example shown in FIGS. 5 and 6, the curve of the reception-level voltage in the main lobe becomes flatter as it approaches the peak. FIG. 6 is an enlarged view of a part of the image of the main lobe within a circle indicated by a dotted line in FIG. 5. In FIG. 6, when the angle of the antenna is changed by Δa [deg], the reception-level voltage is changed by Δb1 [V].

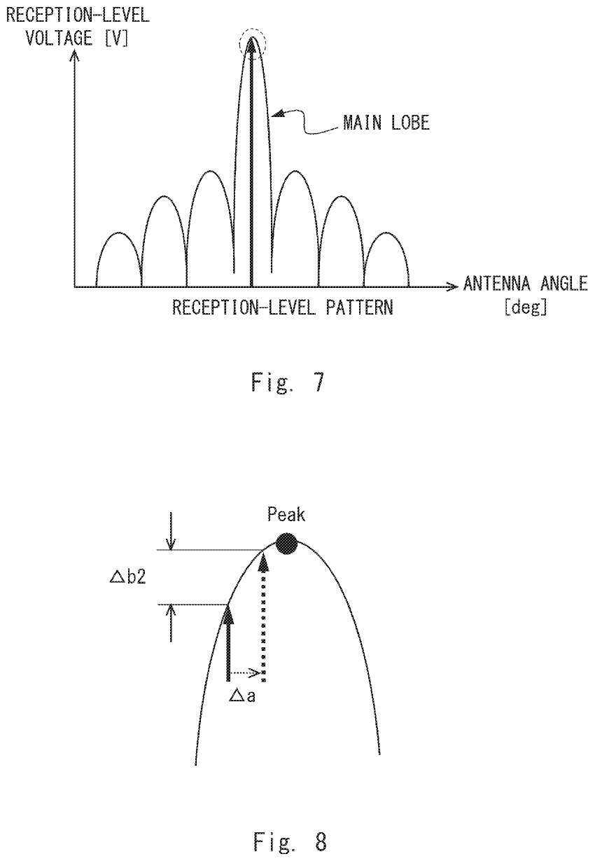

FIGS. 7 and 8 show an example of images displayed in the display device 20 according to the first example embodiment. Specifically, it is an example of images when a reception-level voltage [V] is generated as the second information. That is, it is an example of images in a case where a reception-level voltage [V] is generated by multiplying a reception level [dBm] by first information [V/dBm] which is a coefficient that becomes larger as the reception level becomes higher.

FIG. 8 is an enlarged view of a part of the image of the main lobe within a circle indicated by a dotted line in FIG. 7. In the example shown in FIG. 8, when the angle of the antenna is changed from the same starting position as that in FIG. 6 by Δa [deg], the reception-level voltage is changed by Δb2 [V]. The voltage Δb2 is larger than the voltage Δb1. That is, in the example shown in FIGS. 7 and 8, the change in the reception-level voltage [V] that occurs according to the change in the angle of the antenna in the main lobe is larger than that of the example shown in FIGS. 5 and 6. Therefore, in the example shown in FIGS. 7 and 8, it is easier to detect the change in the reception-level voltage [V] that occurs according to the change in the angle of the antenna as compared to the example shown in FIGS. 5 and 6.

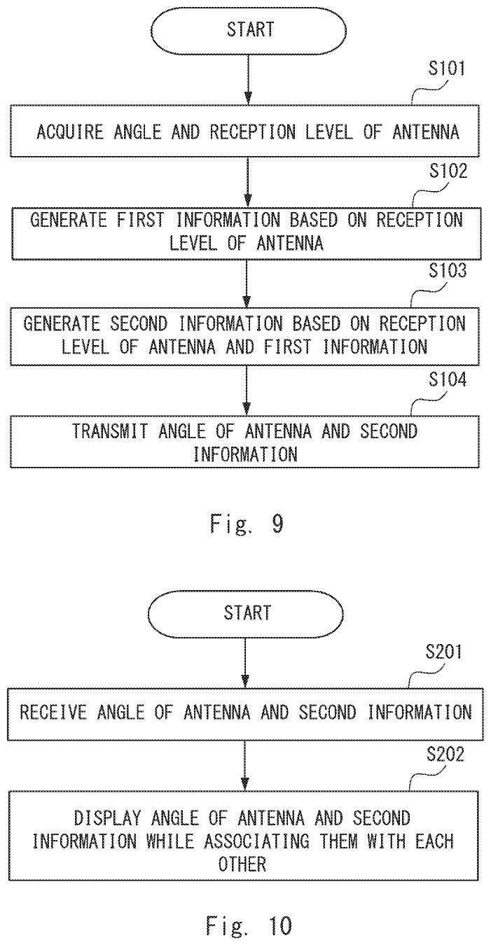

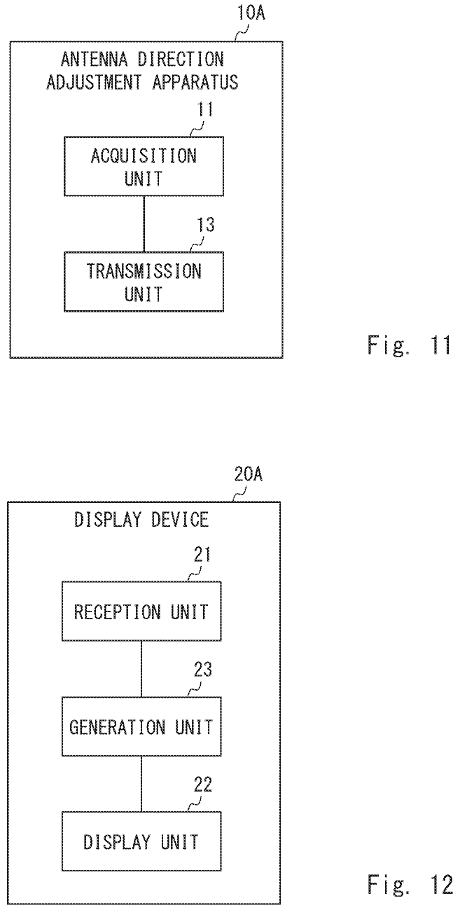

Next, an example of processes performed by the antenna direction adjustment apparatus 10 according to the first example embodiment is described with reference to a flowchart shown in FIG. 9.

Firstly, the acquisition unit 11 of the antenna direction adjustment apparatus 10 acquires an angle of the antenna 1 and a reception level of the antenna 1 at that angle (step S101).

Next, the generation unit 12 of the antenna direction adjustment apparatus 10 generates, based on the reception level of the antenna 1, first information which is a coefficient that becomes larger as the reception level of the antenna 1 becomes higher (step S102).

Next, the generation unit 12 of the antenna direction adjustment apparatus 10 generates second information based on the reception level of the antenna 1 and the first information (step S103).

Next, the transmission unit 13 of the antenna direction adjustment apparatus 10 transmits the angle of the antenna 1 and the second information to the display device 20 (step S104).

Next, an example of processes performed by the display device 20 according to the first example embodiment is described with reference to a flowchart shown in FIG. 10.

Firstly, the reception unit 21 of the display device 20 receives an angle of the antenna 1 and second information from the antenna direction adjustment apparatus 10 (step S201).

Next, the display unit 22 of the display device 20 displays the angle of the antenna 1 and the second information while associating them with each other (step S202).

As described above, the antenna direction adjustment apparatus 10 according to the first example embodiment of the present invention includes the generation unit 12 that generates, based on the reception level of the antenna 1, first information which is a coefficient that becomes larger as the reception level becomes higher. Further, the generation unit 12 is configured to generate second information based on the reception level of the antenna 1 and the first information. Further, the antenna direction adjustment apparatus 10 includes the transmission unit 13 that transmits the angle of the antenna 1 and the second information to the display device 20. In this way, in the antenna direction adjustment apparatus 10, it is possible to transmit the second information, which is generated based on the first information, which is a coefficient that becomes larger as the reception level of the antenna 1 becomes higher, and the reception level of the antenna 1, to the display device 20 together with the angle of the antenna 1. Therefore, in the antenna direction adjustment apparatus 10 according to the first example embodiment, it is possible to alleviate the difficulty of the operation for adjusting the direction of the antenna.

Further, the display device 20 according to the first example embodiment of the present invention includes the reception unit 21 that receives the angle of the antenna 1 and the second information from the antenna direction adjustment apparatus 10. Further, the display device 20 includes the display unit 22 that displays the angle of the antenna 1 and the second information while associating them with each other. In this way, in the display device 20 according to the first example embodiment, it is possible to increase the change in the second information that occurs according to the change in the angle of the antenna in the region near the peak of the main lobe. Therefore, in the display device 20 according to the first example embodiment, it is possible to alleviate the difficulty of the operation for adjusting the direction of the antenna.

Further, the antenna direction adjustment system 100 according to the first example embodiment of the present invention includes the antenna direction adjustment apparatus 10 and the display device 20. Therefore, in the antenna direction adjustment system 100 according to the first example embodiment, it is possible to alleviate the difficulty of the operation for adjusting the direction of the antenna.

### Modified Example of First Example Embodiment

Next, an antenna direction adjustment system 100A according to a modified example of the first example embodiment of the present invention is described. The antenna direction adjustment system 100A includes an antenna direction adjustment apparatus 10A and a display device 20A.

Firstly, a configuration example of the antenna direction adjustment apparatus 10A is described with reference to a block diagram shown in FIG. 11. The antenna direction adjustment apparatus 10A includes an acquisition unit 11 and a transmission unit 13.

The acquisition unit 11 has a configuration similar to that of the acquisition unit 11 according to the first example embodiment. The acquisition unit 11 outputs an acquired angle and a reception level of the antenna 1 to the transmission unit 13.

The transmission unit 13 receives the angle and the reception level of the antenna 1 from the acquisition unit 11. Further, the transmission unit 13 transmits the received angle and the reception level of the antenna 1 to the display device 20A.

Next, the display device 20A according to the modified example of the first example embodiment is described with reference to a block diagram shown in FIG. 12. The display device 20A includes a reception unit 21, a generation unit 23, and a display unit 22.

The reception unit 21 receives the angle and the reception level of the antenna 1 from the antenna direction adjustment apparatus 10A. Further, the reception unit 21 outputs the received angle and the reception level of the antenna 1 to the generation unit 23.

The generation unit 23 has a function similar to that of the generation unit 12 of the antenna direction adjustment apparatus 10 according to the first example embodiment. The generation unit 23 receives the angle and the reception level of the antenna 1 from the reception unit 21. Further, the generation unit 23 generates first information based on the received reception level.

Further, the generation unit 23 generates second information based on the reception level of the antenna 1 and the first information. Then, the generation unit 23 outputs the angle of the antenna 1 and the second information to the display unit 22.

The display unit 22 receives the angle of the antenna 1 and the second information from the generation unit 23. Further, the display unit 22 displays the angle of the antenna 1 and the second information while associating them with each other.

As described above, the antenna direction adjustment system 100A according to the modified example of the first example embodiment of the present invention is configured so that the generation unit is provided in the display device instead of being provided in the antenna direction adjustment apparatus. Further, the antenna direction adjustment system 100A according to the modified example of the first example embodiment can provide advantageous effects similar to those of the antenna direction adjustment system 100 according to the first example embodiment.

### Second Example Embodiment

Next, an antenna direction adjustment system 100B according to a second example embodiment of the present invention is described. The antenna direction adjustment system 100B includes an antenna direction adjustment apparatus 10B and a display device 20. The display device 20 is similar to the display device 20 according to the first example embodiment and therefore its description is omitted.

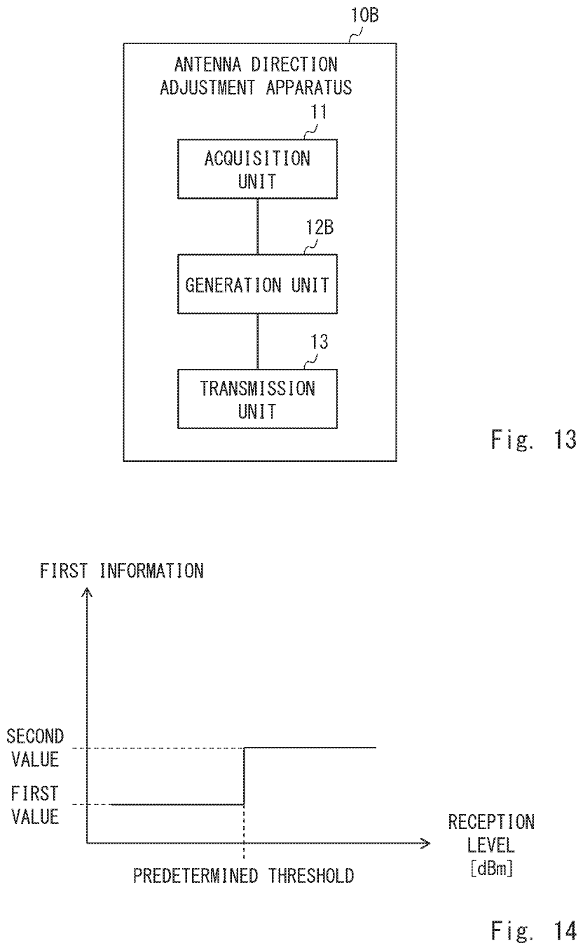

A configuration example of the antenna direction adjustment apparatus 10B is described with reference to a block diagram shown in FIG. 13. The antenna direction adjustment apparatus 10B includes an acquisition unit 11, a generation unit 12B, and a transmission unit 13. Note that the acquisition unit 11 and the transmission unit 13 of the antenna direction adjustment apparatus 10B are similar to the acquisition unit 11 and the transmission unit 13 of the antenna direction adjustment apparatus 10 according to the first example embodiment, and therefore their descriptions are omitted.

The generation unit 12B receives an angle and a reception level of the antenna 1 from the acquisition unit 11. Further, the generation unit 12B compares the received reception level with a predetermined threshold. Note that the predetermined threshold is a threshold that is calculated based on conditions such as the frequency, the antenna gain, and the radio-wave propagation environment. Note that the predetermined threshold may be set to a value higher than the peak of the side lobe in the reception-level pattern, so that it can be recognized that when the reception level is higher than the predetermined threshold, it is in the region of the main lobe.

The generation unit 12B switches the first information depending on whether the reception level is equal to or lower than the predetermined threshold or it is higher than the predetermined threshold. Note that the first information that is used when the reception level is equal to or lower than the predetermined threshold may be used as a coefficient for a coarse adjustment of the angle of the antenna 1, and the first information that is used when the reception level is higher than the predetermined threshold may be used as a coefficient for a fine adjustment of the angle of the antenna 1.

Further, the generation unit 12B generates second information based on the reception level and the first information. Then, the generation unit 12B outputs the angle of the antenna 1 and the second information to the transmission unit 13.

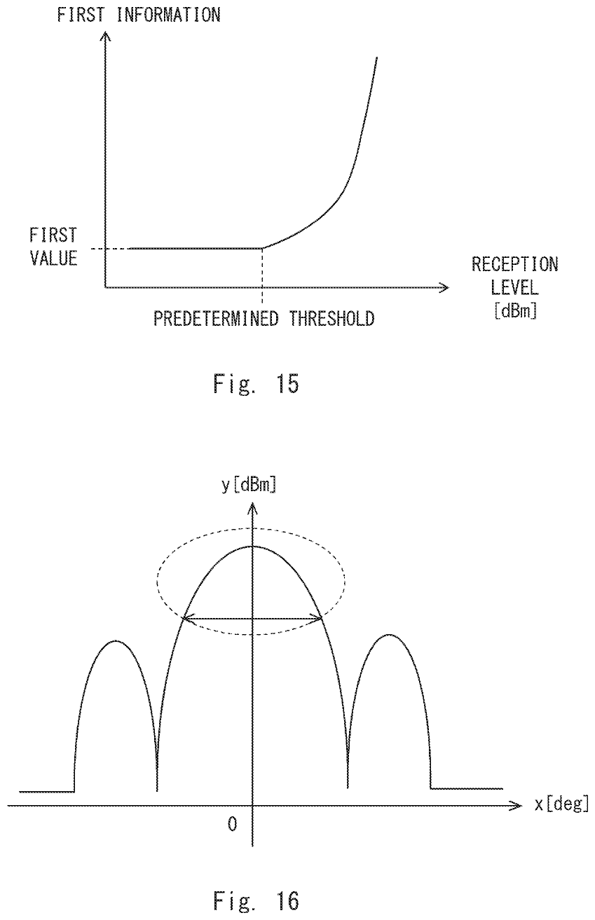

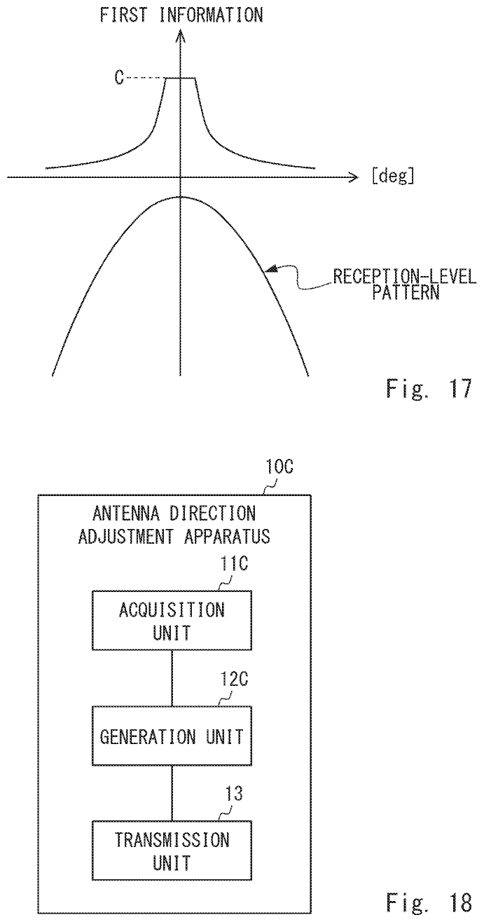

Next, first information according to the second example embodiment is described with reference to FIGS. 14 and 15. FIG. 14 is a graph showing an example of the first information according to the second example embodiment. In the example shown in FIG. 14, when the reception level is equal to or lower than the predetermined threshold, the first information is fixed to a first value. Further, when the reception level is higher than the predetermined threshold, the first information is fixed to a second value. That is, in the example shown in FIG. 14, the first information is switched in a stepwise manner depending on whether the reception level is equal to or lower than the predetermined threshold or it is higher than the predetermined threshold.

FIG. 15 is a graph showing another example of the first information according to the second example embodiment. In the example shown in FIG. 15, when the reception level is equal to or lower than the predetermined threshold, the first information is fixed to a first value. Further, when the reception level is higher than the predetermined threshold, the first information is increased as the reception level becomes higher.

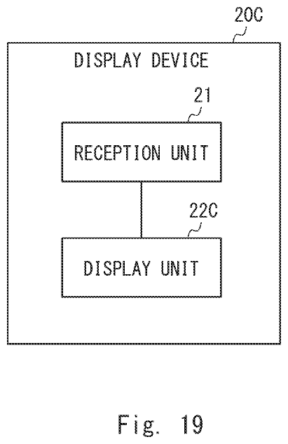

Next, a specific example of a method for generating first information when the reception level is higher than the predetermined threshold in the example shown in FIG. 15 is described with reference to FIGS. 16 and 17. FIG. 16 is a graph showing an example of a model of a reception-level pattern showing a relation between the angle and the reception level of an antenna. Note that the model of the reception-level pattern is calculated, for example, based on conditions such as the frequency, the antenna gain, and the radio-wave propagation environment.

Note that it may be assumed that a part of the reception-level pattern within a circle indicated by a dotted line in FIG. 16 is a part in which the reception level is higher than the predetermined threshold. The following description is given on the assumption that the part of the reception-level pattern within the circle indicated by dotted lines in FIG. 16 is the part in which the reception level is higher than the predetermined threshold.

By expressing the part of the reception-level pattern within the circle indicated by dotted lines in FIG. 16 by a parabola y=A*x²+B in an approximate manner, it is possible to obtain a parabola y=A*x²+B (A and B are known) for the antenna 1.

Next, by using the parabola y=A*x²+B for the antenna 1, an angle x1 [deg] is calculated from the reception level y1 [dBm] of the antenna 1 acquired by the acquisition unit 11.

Next, a coefficient that is proportional to the reciprocal of the inclination of the tangent of the parabola y=A*x²+B for the antenna 1 is calculated. That is, the coefficient is an absolute value of D/(2A*x1). Note that D is a constant. In the example shown in FIG. 15, this coefficient is the first information that is used when the reception level is higher than the predetermined threshold.

FIG. 17 is a graph showing a relation between the part of the reception-level pattern within the circle indicated by the dotted line in FIG. 16 and the coefficient. As the inclination (a differential value) of the reception-level pattern becomes smaller, the first information (the coefficient) becomes larger. However, the first information may be clamped at a predetermined value C.

Note that in the above-described example, an example in which the absolute value of D/(2A*x1) is used as the first information that is used when the reception level is higher than the predetermined threshold is described. However, the first information is not limited to such examples. For example, a value obtained by multiplying the absolute value of D/(2A*x1) by the first information that is used when the reception level is equal to or lower than the predetermined threshold (i.e., by the first value) may be used as the first information that is used when the reception level is higher than the predetermined threshold.

As described above, the antenna direction adjustment system 100B according to the second example embodiment of the present invention is configured so that the antenna direction adjustment apparatus 10B includes the generation unit 12B. Further, the antenna direction adjustment system 100B is configured so that the generation unit 12B compares the reception level with the predetermined threshold and switches the first information depending on whether the reception level is equal to or lower than the predetermined threshold or it is higher than the predetermined threshold. In this way, in the antenna direction adjustment system 100B according to the second example embodiment, it is possible to adopt a large coefficient as the first information only in the region where the reception level is higher than the predetermined threshold. Therefore, for example, it is possible to adopt a large coefficient as the first information only in the region where the reception-level pattern is flat by setting a predetermined threshold for the region where the reception-level pattern is flat, such as setting a value that is lower than the estimated peak of the main lobe by 3 dB. Further, in this case, a fixed value can be used as the first information in the side lobe.

Note that in the antenna direction adjustment system 100B according to the second example embodiment, the antenna direction adjustment apparatus 10B or the display device 20 may notify an operator by producing a sound or displaying a message when the reception level becomes higher than the predetermined threshold value. In this way, in the antenna direction adjustment system 100B, as the operator receives the notification, he/she can recognize that it is in the region where a fine adjustment is required.

### Third Example Embodiment

Next, an antenna direction adjustment system 100C according to a third example embodiment of the present invention is described. The third example embodiment relates to an example in which both the elevation angle and the azimuth angle of the antenna 1 are adjusted. The antenna direction adjustment system 100C includes an antenna direction adjustment apparatus 10C and a display device 20C.

A configuration example of the antenna direction adjustment apparatus 10C is described with reference to a block diagram shown in FIG. 18. The antenna direction adjustment apparatus 10C includes an acquisition unit 11C, a generation unit 12C, and a transmission unit 13.

The acquisition unit 11C acquires both the elevation angle and the azimuth angle of the antenna 1. Further, the acquisition unit 11C acquires a reception level of the antenna 1 for the elevation angle of the antenna 1 and a reception level of the antenna 1 for the azimuth angle of the antenna 1. Then, the acquisition unit 11C outputs the elevation angle and the azimuth angle of the antenna 1, the reception level of the antenna 1 for the elevation angle of the antenna 1, and the reception level of the antenna 1 for the azimuth angle of the antenna 1 to the generation unit 12C.

The generation unit 12C receives the elevation angle and the azimuth angle of the antenna 1, the reception level of the antenna 1 for the elevation angle of the antenna 1, and the reception level of the antenna 1 for the azimuth angle of the antenna 1 from the acquisition unit 11C. Further, the generation unit 12C generates first information for the elevation angle of the antenna 1 based on the reception level for the elevation angle of the antenna 1. Further, the generation unit 12C generates first information for the azimuth angle of the antenna 1 based on the reception level for the azimuth angle of the antenna 1.

Further, the generation unit 12C generates second information for the elevation angle of the antenna 1 based on the reception level for the elevation angle of the antenna 1 and the first information for the elevation angle of the antenna 1. As a specific example, the generation unit 12C generates the second information for the elevation angle of the antenna 1 by multiplying the reception level for the elevation angle of the antenna 1 by the first information for the elevation angle of the antenna 1.

Similarly, the generation unit 12C generates second information for the azimuth angle of the antenna 1 by multiplying the reception level for the azimuth angle of the antenna 1 by the first information for the azimuth angle of the antenna 1. Then, the generation unit 12C outputs the elevation angle and the azimuth angle of the antenna 1, the second information for the elevation angle of the antenna 1, and the second information for the azimuth angle of the antenna 1 to the transmission unit 13.

The transmission unit 13 receives the elevation angle and the azimuth angle of the antenna 1, the second information for the elevation angle of the antenna 1, and the second information for the azimuth angle of the antenna 1 from the generation unit 12C. Then, the transmission unit 13 transmits the received information to the display device 20C.

Next, a configuration example of the display device 20C is described with reference to a block diagram shown in FIG. 19. The display device 20C includes a reception unit 21 and a display unit 22C.

The reception unit 21 receives the elevation angle and the azimuth angle of the antenna 1, the second information for the elevation angle of the antenna 1, and the second information for the azimuth angle of the antenna 1 from the antenna direction adjustment apparatus 10C. Further, the reception unit 21 outputs the received information to the display unit 22C.

The display unit 22C receives the elevation angle and the azimuth angle of the antenna 1, the second information for the elevation angle of the antenna 1, and the second information for the azimuth angle of the antenna 1 from the reception unit 21. Further, the display unit 22C displays a first display in which the second information for the elevation angle of the antenna 1 is associated with the elevation angle of the antenna 1, and a second display in which the second information for the azimuth angle of the antenna 1 is associated with the azimuth angle of the antenna 1.

Further, the display unit 22C may generate a coordinate system in which a horizontal axis indicates one of the elevation angle and the azimuth angle of the antenna 1 and a vertical axis indicates the other of the elevation angle and the azimuth angle, and display a third display in which the second information for the elevation angle and the second information for the azimuth angle are drawn in the coordinate system.

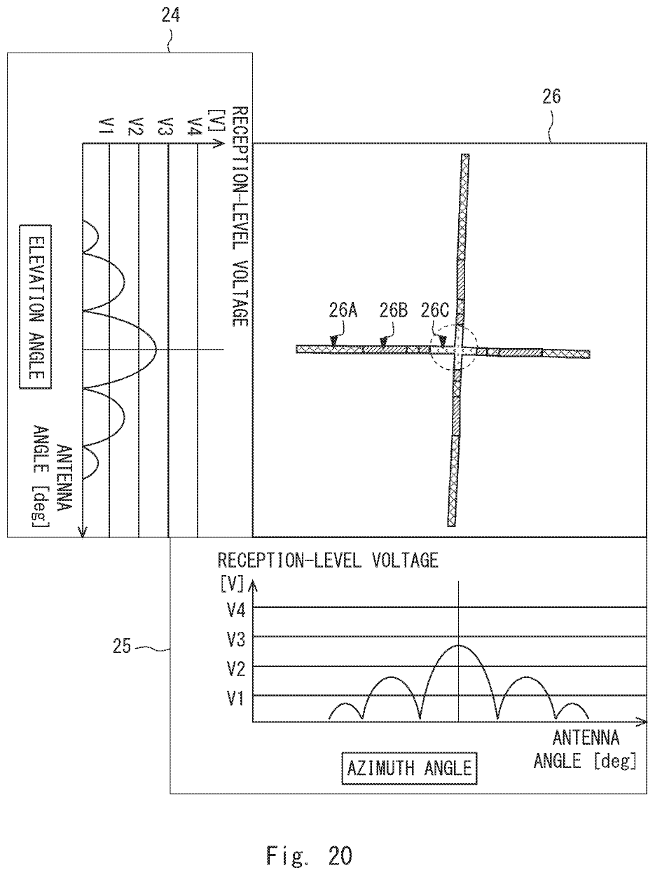

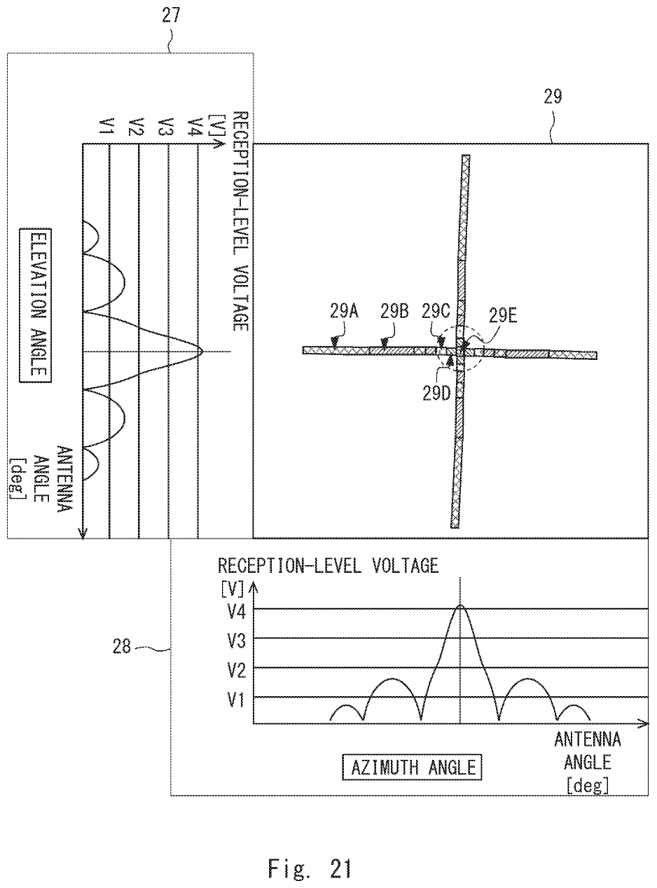

Next, a comparison between an image displayed in the display device according to the third example embodiment and an image according to a comparative example is described with reference to FIGS. 20 to 21. Note that FIGS. 20 and 21 show an example case in which a display in which the reception-level voltage of the antenna is associated with the elevation angle thereof, a display in which the reception-level voltage of the antenna is associated with the azimuth angle thereof, and a display in which the reception-level voltage for the elevation angle and the reception-level voltage for the azimuth angle are drawn in the coordinate system are displayed.

FIG. 20 shows an example of images in a case where a reception-level voltage [V] is generated by multiplying a reception level [dBm] by a fixed coefficient [V/dBm] without using the first information. In the example shown in FIG. 20, a display 24 in which the reception-level voltage for the elevation angle of the antenna is associated with the elevation angle thereof, a display 25 in which the reception-level voltage for the azimuth angle of the antenna is associated with the azimuth angle thereof, and a display 26 are displayed.

In the example shown in FIG. 20, in the displays 24 and 25, the curve of the reception-level voltage in the main lobe becomes flatter as it approaches the peak as in the case of the example shown in FIGS. 5 and 6.

The display 26 is a coordinate system in which a horizontal axis indicates the elevation angle of the antenna and a vertical axis indicates the azimuth angle of the antenna. In the display 26, the reception-level voltage for the elevation angle of the antenna and the reception-level voltage for the azimuth angle of the antenna are drawn. Specifically, a region where the reception-level voltage is equal to or lower than a voltage V1 is drawn by a first visual representation 26A. Further, a region where the reception-level voltage is higher than the voltage V1 and no higher than a voltage V2 is drawn by a second visual representation 26B. Further, a region where the reception-level voltage is higher than the voltage V2 and no higher than a voltage V3 is drawn by a third visual representation 26C. Note that the first, second and third visual representations 26A, 26B and 26C are visual representations different from each other and hence can be visually identified from each other. For example, the first, second and third visual representations 26A, 26B and 26C have colors and/or patterns different from each other.

In the display 26 shown in FIG. 20, the area within the circle indicated by the dotted line is drawn by the third visual representation 26C. Therefore, because the area within the circle indicated by the dotted line is drawn by the same visual expression, it is difficult to determine the peak of the reception-level voltage in the display 26.

FIG. 21 shows an example of an image displayed in the display device 20C according to the third example embodiment. Specifically, it is an example of an image when a reception-level voltage is generated as second information. In the example shown in FIG. 21, a first display 27 in which the reception-level voltage for the elevation angle of the antenna 1 is associated with the elevation angle thereof, a second display 28 in which the reception-level voltage for the azimuth angle of the antenna 1 is associated with the azimuth angle thereof, and a third display 29 are displayed.

The first and second displays 27 and 28 are similar to those in the example shown in FIGS. 7 and 8, and therefore their descriptions are omitted.

The third display 29 is a coordinate system in which a horizontal axis indicates the elevation angle of the antenna 1 and a vertical axis indicates the azimuth angle of the antenna 1 as in the case of the display 26 shown in FIG. 20. In the third display 29, the regions where the reception-level voltage is equal to or lower than the voltage V2 are displayed in a manner similar to that of the display 26 shown in FIG. 20. That is, the region where the reception-level voltage is equal to or lower than the voltage V1 is drawn by a first visual representation 29A. Further, the region where the reception-level voltage is higher than the voltage V1 and no higher than the voltage V2 is drawn by a second visual representation 29B.

In the third display 29, a visual representation within a circle indicated by a dotted line is drawn in a detailed manner as compared to the display 26 shown in FIG. 20. Specifically, a region where the reception-level voltage is higher than the voltage V2 and no higher than a voltage V3 is drawn by a third visual representation 29C. Further, a region where the reception-level voltage is higher than the voltage V3 and no higher than a voltage V4 is drawn by a fourth visual representation 29D. Further, a region where the reception-level voltage is higher than the voltage V4 is drawn by a fifth visual representation 29E.

In the example shown in FIG. 21, a visual representation within the circle indicated by the dotted line is drawn in a detailed manner as compared to the example shown in FIG. 20. Therefore, in the example shown in FIG. 21, it is easier to detect the change in the reception-level voltage that occurs according to the change in the angle of the antenna as compared to the example shown in FIG. 20.

Note that in the example shown in FIG. 21, an example in which the first, second and third displays 27, 28 and 29 are displayed is shown. However, the display is not limited to such examples. Only the first and second displays 27 and 28 may be displayed, or only the third display 29 may be displayed.

As described above, in the display device 20C according to the third example embodiment of the present invention, the reception unit 21 is configured to receive the elevation angle and the azimuth angle of the antenna 1, the second information for the elevation angle of the antenna 1, and the second information for the azimuth angle of the antenna 1. Further, the display device 20C is configured so that the display unit 22C displays the first display in which the second information for the elevation angle of the antenna 1 is associated with the elevation angle of the antenna 1, and the second display in which the second information for the azimuth angle of the antenna 1 is associated with the azimuth angle of the antenna 1. In this way, in the display device 20C according to the third example embodiment, it is possible to alleviate the difficulty of the operation for adjusting the direction of the antenna 1 for both the elevation angle and the azimuth angle thereof.

Further, the display device 20C according to the third example embodiment is configured so that the display unit 22C generates a coordinate system in which a horizontal axis indicates one of the elevation angle and the azimuth angle of the antenna 1 and a vertical axis indicates the other of the elevation angle and the azimuth angle, and displays a third display in which the second information for the elevation angle and the second information for the azimuth angle are drawn in the coordinate system. In this way, the display device 20C according to the third example embodiment can display a coordinate system in which the second information for the elevation angle and the second information for the azimuth angle are combined with each other. Therefore, it is possible to alleviate the difficulty of the operation for adjusting the direction of the antenna 1 for both the elevation angle and the azimuth angle thereof even further.

Note that in the above-described first to third example embodiments, examples in which only the vertical axis, which indicates, for example, the reception-level voltage of the antenna, is enlarged are described. However, the horizontal axis, which indicates the angle of the antenna, may also be enlarged. For example, the horizontal axis may be enlarged so that no side lobe is displayed and only the main lobe is displayed. Note that in order to prevent the reception-level pattern from becoming flat, the enlargement of the horizontal axis is preferably smaller than the enlargement of the vertical axis.

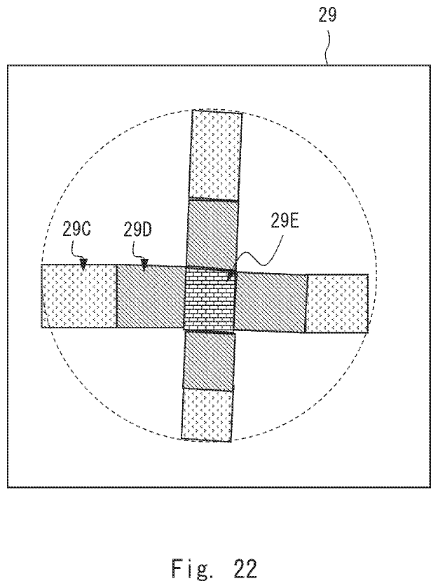

Similarly, a part of the third display 29 shown in FIG. 21 may also be enlarged as shown in FIG. 22. FIG. 22 shows an example in which the area within a circle indicated by a dotted line in FIG. 21 is displayed in an enlarged manner.

Processes performed in each of the antenna direction adjustment apparatus and the display device described in the above-described first to third example embodiments can be implemented by using a computer system, such as an ASIC (Application Specific Integrated the Circuit), a DSP (Digital Signal Processor), an MPU (Micro Processing Unit), a CPU (Central Processing Unit), or a combination thereof, provided in the antenna direction adjustment apparatus and the display device. Specifically, they may be implemented by having the computer system execute a program including a group of instructions related to a process performed by each functional unit in the antenna direction adjustment apparatus and the display device described above with reference to a block diagram or a flowchart.

In the above-described examples, the program may be stored in various types of non-transitory computer readable media and thereby supplied to computers. The non-transitory computer readable media includes various types of tangible storage media. Examples of the non-transitory computer readable media include a magnetic recording medium (such as a flexible disk, a magnetic tape, and a hard disk drive), a magneto-optic recording medium (such as a magneto-optic disk), a CD-ROM (Read Only Memory), a CD-R, a CD-R/W, and a semiconductor memory (such as a mask ROM, a PROM (Programmable ROM), an EPROM (Erasable PROM), a flash ROM, and a RAM (Random Access Memory). These programs may be supplied to computers by using various types of transitory computer readable media. Examples of the transitory computer readable media include an electrical signal, an optical signal, and an electromagnetic wave. The transitory computer readable media can be used to supply programs to a computer through a wired communication line (e.g., electric wires and optical fibers) or a wireless communication line.

Although the present invention is described above with reference to embodiments, the present invention is not limited to the above-described embodiments. Various modifications that can be understood by those skilled in the art can be made to the configuration and details of the present invention within the scope of the invention.

For example, the whole or part of the example embodiments disclosed above can be described as, but not limited to, the following supplementary notes.

### (Supplementary Note 1)

An antenna direction adjustment apparatus comprising:

acquisition means for acquiring at least one of an elevation angle and an azimuth angle of an antenna, and a reception level of the antenna at the angle;

generation means for generating first information based on the reception level, and generating second information based on the reception level and the first information; and

transmission means for transmitting the angle and the second information to a display device, wherein

the first information is a coefficient that becomes larger as the reception level becomes higher.

### (Supplementary Note 2)

The antenna direction adjustment apparatus described in Supplementary note 1, wherein the generation means generates the second information by multiplying the reception level by the first information.

### (Supplementary Note 3)

The antenna direction adjustment apparatus described in Supplementary note 1 or 2, wherein the generation means compares the reception level with a predetermined threshold and switches the first information depending on whether the reception level is equal to or lower than the predetermined threshold or it is higher than the predetermined threshold.

### (Supplementary Note 4)

The antenna direction adjustment apparatus described in Supplementary note 3, wherein when the reception level is higher than the predetermined threshold, the generation means increases the coefficient, which is the first information, as the reception level becomes higher.

### (Supplementary Note 5)

A display device comprising:

receiving means for receiving at least one of an elevation angle and an azimuth angle of an antenna, and second information from an antenna direction adjustment apparatus; and

display means for displaying the angle and the second information while associating them with each other, wherein

the second information is information based on the reception level of the antenna and first information, and

the first information is a coefficient that becomes larger as the reception level of the antenna becomes higher.

### (Supplementary Note 6)

The display device described in Supplementary note 5, wherein the second information is information obtained by multiplying the reception level by the first information

### (Supplementary Note 7)

The display device described in Supplementary note 5 or 6, wherein

the receiving means receives the elevation angle and the azimuth angle of the antenna, the second information for the elevation angle of the antenna, and the second information for the azimuth angle of the antenna, and

the display means displays a first display in which the second information for the elevation angle of the antenna is associated with the elevation angle thereof, and a second display in which the second information for the azimuth angle of the antenna is associated with the azimuth angle thereof.

### (Supplementary Note 8)

The display device described in any one of Supplementary notes 5 to 7, wherein

the receiving means receives the elevation angle and the azimuth angle of the antenna, the second information for the elevation angle of the antenna, and the second information for the azimuth angle of the antenna, and

the display means generates a coordinate system in which a horizontal axis indicates one of the elevation angle and the azimuth angle of the antenna and a vertical axis indicates the other of the elevation angle and the azimuth angle, and displays a third display in which the second information for the elevation angle and the second information for the azimuth angle are drawn in the coordinate system.

### (Supplementary Note 9)

An antenna direction adjustment system comprising an antenna direction adjustment apparatus and a display device, wherein

the antenna direction adjustment apparatus comprises acquisition means for acquiring at least one of an elevation angle and an azimuth angle of an antenna, and a reception level of the antenna at the angle,

the antenna direction adjustment apparatus or the display device comprises generation means for generating first information based on the reception level, and generating second information based on the reception level and the first information,

the display device comprises display means for displaying the angle and the second information while associating them with each other, and

the first information is a coefficient that becomes larger as the reception level of the antenna becomes higher.

### (Supplementary Note 10)

A method performed in an antenna direction adjustment apparatus, comprising:

acquiring at least one of an elevation angle and an azimuth angle of an antenna, and a reception level of the antenna at the angle;

generating first information based on the reception level, the first information being a coefficient that becomes larger as the reception level becomes higher;

generating second information based on the reception level and the first information; and

transmitting the angle and the second information to a display device.

### (Supplementary Note 11)

A method performed in a display device, comprising:

receiving at least one of an elevation angle and an azimuth angle of an antenna, and second information from an antenna direction adjustment apparatus; and

displaying the angle and the second information while associating them with each other, wherein

the second information is information based on the reception level of the antenna and first information, and

the first information is a coefficient that becomes larger as the reception level of the antenna becomes higher.

### (Supplementary Note 12)

A method performed in an antenna direction adjustment system, comprising:

acquiring at least one of an elevation angle and an azimuth angle of an antenna, and a reception level of the antenna at the angle;

generating first information based on the reception level, the first information being a coefficient that becomes larger as the reception level becomes higher;

generating second information based on the reception level and the first information; and

displaying the angle and the second information while associating them with each other.

This application is based upon and claims the benefit of priority from Japanese patent application No. 2017-052922, filed on Mar. 17, 2017, the disclosure of which is incorporated herein in its entirety by reference.

### REFERENCE SIGNS LIST

1 ANTENNA
10, 10A, 10B, 10C ANTENNA DIRECTION ADJUSTMENT UNIT
11, 11C ACQUISITION UNIT
12, 12B, 12C GENERATION UNIT
13 TRANSMISSION UNIT
20, 20A, 20C DISPLAY DEVICE
21 RECEPTION UNIT
22, 22C DISPLAY UNIT
23 GENERATION UNIT

1. An antenna direction adjustment apparatus comprising:
acquisition unit configured to acquire at least one of an elevation angle and an azimuth angle of an antenna, and a reception level of the antenna at the angle;
generation unit configured to generate first information based on the reception level, and generating second information based on the reception level and the first information; and
transmission unit configured to transmit the angle and the second information to a display device, wherein
the first information is a coefficient that becomes larger as the reception level becomes higher.

2. The antenna direction adjustment apparatus according to claim 1, wherein the generation unit generates the second information by multiplying the reception level by the first information.

3. The antenna direction adjustment apparatus according to claim 1, wherein the generation unit compares the reception level with a predetermined threshold and switches the first information depending on whether the reception level is equal to or lower than the predetermined threshold or it is higher than the predetermined threshold.

4. The antenna direction adjustment apparatus according to claim 3, wherein when the reception level is higher than the predetermined threshold, the generation unit increases the coefficient, which is the first information, as the reception level becomes higher.

5-8. (canceled)

9. An antenna direction adjustment system comprising an antenna direction adjustment apparatus and a display device, wherein
the antenna direction adjustment apparatus comprises acquisition unit configured to acquire at least one of an elevation angle and an azimuth angle of an antenna, and a reception level of the antenna at the angle,
the antenna direction adjustment apparatus or the display device comprises generation unit configured to generate first information based on the reception level, and generating second information based on the reception level and the first information,
the display device comprises display unit configured to display the angle and the second information while associating them with each other, and
the first information is a coefficient that becomes larger as the reception level of the antenna becomes higher.

10. A method performed in an antenna direction adjustment apparatus, comprising:
acquiring at least one of an elevation angle and an azimuth angle of an antenna, and a reception level of the antenna at the angle;
generating first information based on the reception level, the first information being a coefficient that becomes larger as the reception level becomes higher;
generating second information based on the reception level and the first information; and
transmitting the angle and the second information to a display device.

11. (canceled)

12. A method performed in an antenna direction adjustment system, comprising:
acquiring at least one of an elevation angle and an azimuth angle of an antenna, and a reception level of the antenna at the angle;
generating first information based on the reception level, the first information being a coefficient that becomes larger as the reception level becomes higher;
generating second information based on the reception level and the first information; and
displaying the angle and the second information while associating them with each other.
